(19) United States
(12) Patent Application Publication
(10) Pub. No.: US 2026/0334054 A1
(43) Pub. Date: Oct. 22, 2026

(54) DISPLAY PANEL AND MANUFACTURING METHOD THEREOF, AND DISPLAY DEVICE

(71) Applicant: BOE Technology Group Co., Ltd., Beijing (CN)

(72) Inventors: Tao WANG, Beijing (CN); Tao SUN, Beijing (CN); Jianchao ZHU, Beijing (CN); Song CUI, Beijing (CN); Zheng LIU, Beijing (CN); Dengyun CHEN, Beijing (CN); Huijuan ZHANG, Beijing (CN); Tong WU, Beijing (CN)

(21) Appl. No.: 18/993,500

(22) PCT Filed: Aug. 14, 2024
(86) PCT No.: PCT/CN2024/112057

§ 371 Date: Jan. 10, 2025

(30) Foreign Application Priority Data
Sep. 28, 2023 (CN) 202311278571.7

(51) Int. Cl. H10K 59/80; H10K 59/12; H10K 59/122

(52) U.S. Cl. CPC H10K 59/873; H10K 59/1201; H10K 59/122

(57) ABSTRACT

The present disclosure provides a display panel including: a substrate, a display function layer, isolation structures, a first encapsulation layer and a first auxiliary layer. Display function layer includes light-emitting elements arranged in an array; isolation structures and the light-emitting elements are alternately arranged in an array on the substrate, and surface of the isolation structure extending in a direction perpendicular to the substrate has a first groove; the first encapsulation layer covers the display function layer, and a second groove is formed in an edge region of the first encapsulation layer close to the isolation structure; in a direction from the isolation structure towards the substrate, the first encapsulation layer is at least partially covered by the isolation structure; and the first auxiliary layer is on a side of the first encapsulation layer away from the display function layer, and is at least partially filled in the second groove. Thus, the display panel may have high resolution, high light extraction efficiency and high reliability.

### TECHNICAL FIELD

The present disclosure relates to the field of display technologies, and in particular, to a display panel and a manufacturing method thereof, and a display device.

### BACKGROUND

At present, with the maturity of OLED (Organic Light-Emitting Diode) technology, in mobile terminals such as mobile phones, OLED display components are increasingly used. Limited by manufacturing techniques, a wide gap between adjacent light-emitting units will result in a small light-emitting area of the light-emitting unit, which further leads to a small aperture ratio and a low light extraction efficiency.

### SUMMARY

Aiming at the shortcomings of the related art, the present disclosure provides a display panel and a manufacturing method thereof, and a display device, to solve the problem of a small light-emitting area, a small aperture ratio or a low light extraction efficiency of the light-emitting unit of the display panel in the related art.

The present disclosure provides a display panel with a display region and a border region surrounding the display region, where the display panel includes: a substrate, a display function layer, isolation structures, a first encapsulation layer, and a first auxiliary layer. The display function layer is in the display region, including a plurality of light-emitting elements arranged in an array, where each of the plurality of light-emitting elements includes a first electrode, a light-emitting layer, and a second electrode sequentially stacked on the substrate; isolation structures and the plurality of light-emitting elements are alternately arranged in an array on the substrate, and a surface of the isolation structure extending in a direction perpendicular to the substrate has a first groove; the first encapsulation layer covers the display function layer, and a second groove is formed in an edge region of the first encapsulation layer close to the isolation structure; in a direction from the isolation structure towards the substrate, the first encapsulation layer is at least partially covered by the isolation structure; and the first auxiliary layer is on a side of the first encapsulation layer away from the display function layer, and is at least partially filled in the second groove.

In this embodiment, isolation structures are added on the display function layer of the display panel, and the surface of the isolation structure extending in the direction perpendicular to the substrate has a first groove, which may partition the light-emitting layers of adjacent light-emitting elements in the display function layer, and the first groove may avoid cross-color or poor display generated by an edge region of the light-emitting layer close to the isolation structure depositing on a side of the isolation structure. In the evaporation process, the light-emitting elements may be evaporated on the entire surface of the display panel first, then the light-emitting elements in the designated regions are retained, and the light-emitting elements in the remaining regions are removed. Therefore, there is no need to use a Fine Metal Mask (FMM) to prepare individual light-emitting elements separately, and the alignment accuracy issue of the FMM during evaporation in this embodiment does not need to be considered. This thereby allows the gap between the light-emitting elements to be designed with a smaller size, to increase the light-emitting area of the light-emitting units and improve the aperture ratio of the display panel.

However, when the isolation structure has a first groove, in the evaporation process, due to the film formation principle of the first encapsulation layer formed on the surface of the display function layer, combined with the structural characteristics of the isolation structure having the first groove, closed air holes (as illustrated in FIG. 1) are easily formed on a side of the isolation structure, which leads to stress accumulation (as illustrated in FIG. 2) at the top end of a side of the isolation structure, which leads to the display panel being prone to expanding cracks and failure in subsequent reliability tests. And due to the accumulation of stress, the pressure resistance characteristics of the isolation structures of the display panel are poor. In the evaporation process, since only the light-emitting elements in the designated regions are retained, the closed air hole in the first encapsulation layer is to be etched to form a second groove. This embodiment considers forming a first auxiliary layer on the first encapsulation layer to fill up the second groove formed after the first encapsulation layer is etched, thereby avoiding stress concentration and improving the pressure resistance and reliability of the display panel.

In addition, since the isolation structure may block the light-emitting layer, and in the evaporation process, the display function layer is covered with a first encapsulation layer, the dual protection mechanism of the isolation structure and the first package layer may be realized to prevent the light-emitting layer from being eroded by water vapor, which may extend the life of the display panel.

In an embodiment, adjacent two of the isolation structures form a first opening, the light-emitting layer and the second electrode are in the first opening, the isolation structure is provided with a conductive portion, adjacent two second electrodes are separated by the isolation structure, the second electrode is lap-joined to the conductive portion of the isolation structure.

In an embodiment, the display panel further includes a pixel definition layer; the pixel definition layer is arranged on a side of the isolation structure facing the substrate, and the pixel definition layer includes a plurality of pixel definition units arranged in an array; and in the direction perpendicular to the substrate, an orthographic projection of the isolation structure onto the substrate is within an orthographic projection of the pixel definition unit onto the substrate.

In an embodiment, a second opening is formed between adjacent two of the pixel definition units, the second opening is located within the first opening, and an opening direction of the second opening is the same as an opening direction of the first opening; and the first electrode is arranged on a side of the second opening facing the substrate, a plurality of the first electrodes are connected to a light-emitting layer respectively, and adjacent two of the first electrodes are separated by the pixel definition layer.

In an embodiment, in the direction perpendicular to the substrate, an orthographic projection of the isolation structure onto the substrate and an orthographic projection of the light-emitting layer onto the substrate are not overlapped.

In an embodiment, the first auxiliary layer includes a light-transmitting material, and the first auxiliary layer is at least partially arranged on a side of the display function layer away from the substrate; and in the direction perpendicular to the substrate, an orthographic projection of the first auxiliary layer onto the substrate at least partially covers an orthographic projection of an edge region of the display function layer close to the isolation structure onto the substrate.

In an embodiment, the display panel further includes a second auxiliary layer, the second auxiliary layer includes a light-transmitting material; and the second auxiliary layer is arranged on a side of the first auxiliary layer facing away from the substrate, a refractive index of the second auxiliary layer is not equal to a refractive index of the first auxiliary layer.

In an embodiment, the display panel further includes a first light shielding layer and a first planarization layer sequentially arranged on a side of the second auxiliary layer away from the first auxiliary layer, the first light shielding layer includes a plurality of first light shielding units arranged spaced apart, the first planarization layer is at least partially arranged in a first spacing region between adjacent two of the first light shielding units, and in the direction perpendicular to the substrate, an orthographic projection of the first spacing region onto the substrate at least partially covers an orthographic projection of the light-emitting layer onto the substrate.

In an embodiment, the display panel further includes a second light shielding layer and a second planarization layer sequentially stacked on the first planarization layer, the second light shielding layer includes a plurality of second light shielding units arranged spaced apart, the second planarization layer is at least partially arranged in a second spacing region between adjacent two of the second light shielding units, in the direction perpendicular to the substrate, an orthographic projection of the second spacing region onto the substrate at least partially covers an orthographic projection of the light-emitting layer onto the substrate, and an orthographic projection of the second light shielding unit onto the substrate covers and is larger than an orthographic projection of the first light shielding unit onto the substrate.

In an embodiment, the display panel further includes a first light adjusting layer and a second light adjusting layer sequentially stacked on the first planarization layer, in the direction perpendicular to the substrate, an overlapping region between an orthographic projection of the first light adjusting layer onto the substrate and an orthographic projection of the second light adjusting layer onto the substrate at least partially covers an orthographic projection of the light-emitting layer onto the substrate.

In an embodiment, the display panel further includes a light filter layer stacked on the second auxiliary layer, the light filter layer includes alternately arranged light shielding units and light filter units, and in the direction perpendicular to the substrate, an orthographic projection of the light filter unit onto the substrate at least partially covers an orthographic projection of the light-emitting layer onto the substrate.

In an embodiment, in a direction from the substrate towards the display function layer, a projection area of an orthographic projection of the isolation structure onto the substrate gradually increases.

In an embodiment, the isolation structure includes a first isolation portion and a second isolation portion sequentially stacked on the substrate, and in the direction perpendicular to the substrate, an orthographic projection of an end face of the first isolation portion facing the second isolation portion onto the substrate is within an orthographic projection of the second isolation portion onto the substrate.

In an embodiment, the isolation structure includes a third isolation portion, a first isolation portion, and a second isolation portion sequentially stacked on the substrate, and in the direction perpendicular to the substrate, an orthographic projection of the second isolation portion onto the substrate is within an orthographic projection of the third isolation portion onto the substrate, and an orthographic projection of the first isolation portion onto the substrate is within an orthographic projection of the second isolation portion onto the substrate.

In an embodiment, the first encapsulation layer is in the border region, and in a direction from the display function layer towards the substrate, a projection area of an orthographic projection of the first encapsulation layer onto the substrate gradually increases.

The present disclosure further provides a method of manufacturing a display panel, including the following steps:
forming a drive circuit layer and a planarization layer stacked on a substrate;
forming a first electrode on the planarization layer;
forming a pixel definition layer on the first electrode, where the pixel definition layer includes a plurality of pixel definition units arranged spaced apart;
forming isolation structures on the plurality of pixel definition units, where a surface of the isolation structure extending in a direction perpendicular to the substrate has a first groove, and forming a first opening between adjacent two of the isolation structures;
forming a light-emitting layer, a second electrode, and a first encapsulation layer stacked in the first opening, where a second groove is formed in an edge region of the first encapsulation layer close to the isolation structure, and in a direction from the isolation structure towards the substrate, the first encapsulation layer is at least partially covered by the isolation structure; and
forming a first auxiliary layer on a side of the first encapsulation layer away from the display function layer, where the first auxiliary layer is at least partially filled in the second groove.

In an embodiment, in the direction parallel to the substrate, the first opening includes a first sub-opening, a second sub-opening, and a third sub-opening arranged in an array, the light-emitting layer includes a first light-emitting layer, a second light-emitting layer, and a third light-emitting layer arranged in an array, the first sub-opening, the second sub-opening, and the third sub-opening correspond to the first light-emitting layer, the second light-emitting layer, and the third light-emitting layer, respectively, light colors emitted by the first light-emitting layer, the second light-emitting layer, and the third light-emitting layer are different; where forming the light-emitting layer, the second electrode, and the first encapsulation layer stacked in the first opening includes:
by using a photolithography technique, sequentially forming the first light-emitting layer in the first sub-opening, the second light-emitting layer in the second sub-opening, and the third light-emitting layer in the third sub-opening, as well as the second electrode and the first encapsulation layer in the first opening.

In an embodiment, after forming the first auxiliary layer on a side of the first encapsulation layer away from the display function layer, the method further includes:

forming a second auxiliary layer on the first auxiliary layer, where a refractive index of the second auxiliary layer is not equal to a refractive index of the first auxiliary layer.

The present disclosure provides a display device including the display panel as described in the above embodiment.

The additional aspects and advantages of present disclosure will be partially provided in the following description, which will become apparent from the following description or will be understood through the practice of present disclosure.

### BRIEF DESCRIPTION OF DRAWINGS

The accompanying drawings, which are incorporated in and constitute a part of the present description, illustrate embodiments consistent with the present disclosure and serve to explain the principles of the present disclosure together with the description.

FIG. 1 is a structural characteristic diagram of an isolation structure in a manufacturing technique according to an embodiment of the present disclosure;

FIG. 2 is a stress simulation diagram of an isolation structure according to an embodiment of the present disclosure;

FIG. 3 is a film layer structure diagram of a display panel according to an embodiment of the present disclosure;

FIG. 4 is a film layer structure diagram of another display panel according to an embodiment of the present disclosure;

FIG. 5 is a film layer structure diagram of another display panel according to an embodiment of the present disclosure;

FIG. 6 is a film layer structure diagram of another display panel according to an embodiment of the present disclosure;

FIG. 7 is a film layer structure diagram of another display panel according to an embodiment of the present disclosure;

FIG. 8 is a film layer structure diagram of another display panel according to an embodiment of the present disclosure;

FIG. 9 is a film layer structure diagram of another display panel according to an embodiment of the present disclosure;

FIG. 10 is a film layer structure diagram of another display panel according to an embodiment of the present disclosure;

FIG. 11 is a film layer structure diagram of another display panel according to an embodiment of the present disclosure;

FIG. 12 is a film layer structure diagram of another display panel according to an embodiment of the present disclosure;

FIG. 13 is a film layer structure diagram of a border region of a display panel according to an embodiment of the present disclosure;

FIG. 14A to FIG. 14G are structure diagrams in respective steps of a method of manufacturing a display panel according to an embodiment of the present disclosure;

FIG. 15A to FIG. 15F are structure diagrams in respective steps of a method of manufacturing a monochromatic light-emitting layer in a display panel according to an embodiment of the present disclosure.

In the drawings: 1—substrate; 2—drive circuit layer; 21—active layer; 22—source electrode; 23—drain electrode; 24—gate electrode; 25—gate insulating layer; 26—interlayer dielectric layer; 3—planarization layer; 4—pixel definition layer; 41-pixel definition unit; 5—isolation structure; 51—first isolation portion; 52—second isolation portion; 53-third isolation portion; 501—first groove; 6—display function layer; 61—first electrode; 62—light-emitting layer; 621—first light-emitting layer; 63—second electrode; 7—first encapsulation layer; 701—second groove; 1—first encapsulation sub-layer; 72—second encapsulation sub-layer; 73—third encapsulation sub-layer; 8—first auxiliary layer; 9—second auxiliary layer; 10—second encapsulation layer; 101—first inorganic layer; 102—first organic layer; 103—second inorganic layer; 11—first light shielding layer; 111—first light shielding unit; 12—first planarization layer; 13—second light shielding layer; 131—second light shielding unit; 14—second planarization layer; 15—first light adjusting layer; 16—second light adjusting layer; 17—third light shielding layer; 18—third planarization layer; 19—light filter layer; 20—photoresist; A1—first spacing region; A2—second spacing region; 100—first opening; 200—second opening.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. The implementations described in the following exemplary embodiments do not represent all implementations consistent with the present disclosure. Conversely, they are merely examples of apparatuses and methods consistent with some aspects of the present disclosure as detailed in the appended claims.

The terms used in this disclosure are merely for the purpose of describing specific embodiments, and are not intended to limit this disclosure. The terms “a,” “said” and “the” of singular forms used in this application and the appended claims are intended to include plural forms, unless the context clearly indicates otherwise. It should also be understood that, the term “and/or” used herein indicates and includes any or all possible combinations of one or more associated listed items.

It should be understood that when describing the structure of components, when a layer or a region is referred to as being “above” or “on a top of” another layer or region, it may mean directly above the other layer or region, or it may also mean that there are other layers or regions between it and the other layer or region. In addition, if the component is flipped, that layer or region is to be “below” or “underneath” the other layer or region.

Research found that, limited by manufacturing techniques and structures, for example, when evaporating a light-emitting layer, a fine metal mask (FMM) is usually used. In the evaporation process, alignment needs to be performed multiple times, and tolerances are reserved between the corresponding regions of pixels to avoid alignment accuracy errors as much as possible. Therefore, there are certain gaps in the evaporating region between the light-emitting elements, and the existence of the gaps reduces the light-emitting area of the pixels on the light-emitting region of the display panel, thereby affecting the aperture ratio and the light-emitting efficiency of the display panel, which thereby results in lower resolution.

The display panel and the manufacturing method thereof, and the display device provided by the present application aim to solve the above technical problems of the related art.

The display panel and the manufacturing method thereof, and the display device in embodiments of present disclosure are described in detail below with reference to the accompanying drawings. If there is no conflict, the features in the embodiments described below may complement or combine with each other.

The present disclosure provides a display panel with a display region and a border region surrounding the display region, as illustrated in FIG. 3, the display panel includes: a substrate 1, a display function layer 6, isolation structures 5, a first encapsulation layer 7, and a first auxiliary layer 8. The display function layer 6 is in the display region, and includes a plurality of light-emitting elements arranged in an array, each of the light-emitting elements includes a first electrode 61, a light-emitting layer 62, and a second electrode 63 sequentially stacked on the substrate 1; the isolation structures 5 and the plurality of light-emitting elements are alternately arranged in an array on the substrate 1, and the surface of the isolation structure 5 extending in a direction perpendicular to the substrate 1 has a first groove 501; the first encapsulation layer 7 covers the display function layer 6, and a second groove 701 is formed in an edge region of the first encapsulation layer 7 close to the isolation structure 5; in a direction from the isolation structure 5 towards the substrate 1, the first encapsulation layer 7 is at least partially covered by the isolation structure 5; and the first auxiliary layer 8 is on a side of the first encapsulation layer 7 away from the display function layer 6, and is at least partially filled in the second groove 701.

In this embodiment, isolation structures 5 are added on the display function layer 6 of the display panel, and the surface of the isolation structure 5 extending in the direction perpendicular to the substrate 1 has the first groove 501, which may partition the light-emitting layers 62 of adjacent light-emitting elements in the display function layer 6, and the first groove 501 may avoid cross-color or poor display generated by an edge region of the light-emitting layer 62 close to the isolation structure 5 depositing on a side of the isolation structure 5. In the evaporation process, the light-emitting elements may be evaporated on the entire surface of the display panel first, then the light-emitting elements in the designated regions are retained, and the light-emitting elements in the remaining regions are removed. Therefore, there is no need to use an FMM to prepare individual light-emitting elements separately, and the alignment accuracy issue of the FMM mask during evaporation in this embodiment does not need to be considered. This thereby allows the gap between the light-emitting elements to be designed with a smaller size, to increase the light-emitting area of the light-emitting units and improve the aperture ratio of the display panel.

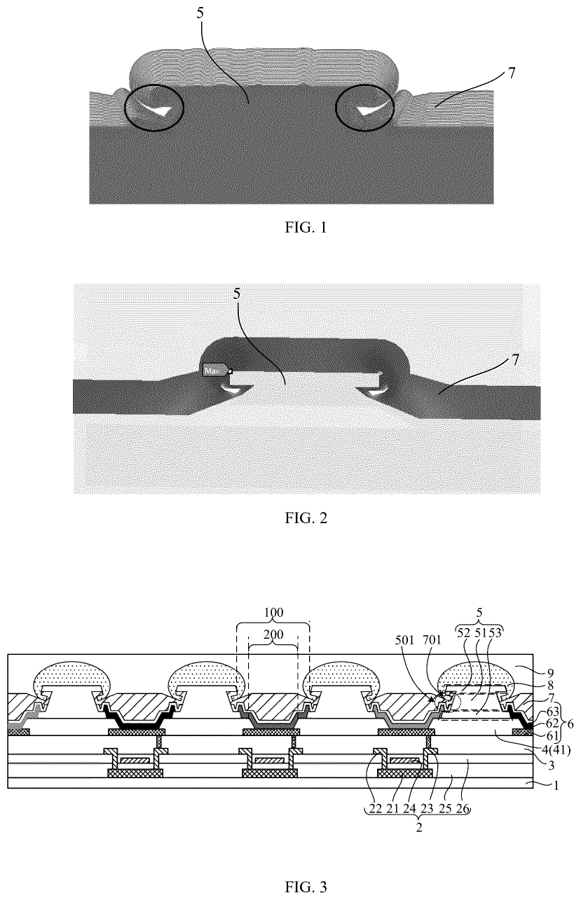

However, when the isolation structure 5 has a first groove 501, in the evaporation process, due to the film formation principle of the first encapsulation layer 7 formed on the surface of the display function layer 6, combined with the structural characteristics of the isolation structure 5 having the first groove 501, a closed air hole (as illustrated in FIG. 1) is easily formed on a side of the isolation structure 5, which leads to stress accumulation (as illustrated in FIG. 2) at the top end of a side of the isolation structure 5, and leads to the display panel being prone to expanding cracks and failure in subsequent reliability tests. And due to the accumulation of stress, the pressure resistance characteristics of the isolation structures 5 of the display panel are poor. In the evaporation process, since only the light-emitting elements in the designated regions are retained, the closed air hole in the first encapsulation layer 7 is to be etched to form a second groove 701. In this embodiment, a first auxiliary layer 8 is formed on the first encapsulation layer 7 to fill up the second groove 701 formed after the first encapsulation layer 7 is etched, thereby avoiding stress concentration and improving the pressure resistance and reliability of the display panel.

In addition, since the isolation structure 5 may block the light-emitting layer 62, and in the evaporation process, the display function layer 6 is covered with a first encapsulation layer 7, the dual protection mechanism of the isolation structure 5 and the first encapsulation layer 7 may be realized to prevent the light-emitting layer 62 from being eroded by water vapor, which may extend the life of the display panel.

In some embodiments, the first encapsulation layer 7 includes an inorganic material, and the first auxiliary layer 8 includes an organic material.

In some embodiments, the first electrode 61 and the second electrode 63 have opposite electrical properties. For example, the first electrode 61 is an anode, and the second electrode 63 is a cathode. For another example, the first electrode 61 is a cathode, and the second electrode 63 is an anode.

In some embodiments, the side of the substrate 1 close to the display function layer 6 is also covered with a buffer layer (not illustrated). The buffer layer is an inorganic thin film, which may be SiNₓ, SiOₓ, or a composite layer.

In some embodiments, as illustrated in FIG. 3, the display panel further includes a drive circuit layer 2, where the drive circuit layer 2 includes an active layer 21, a gate insulating layer 25 and a gate electrode 24 stacked on the active layer 21, as well as a source electrode 22 and a drain electrode 23 connected to two ends of the active layer 21. The source electrode and drain electrode are separated from the gate electrode by an interlayer dielectric layer 26. The drive circuit layer 2 is electrically connected to the first electrode 61 and is configured to control the light emission of the light-emitting element.

In some embodiments, as illustrated in FIG. 3, the display panel further includes a planarization layer 3 between the drive circuit layer 2 and the first electrode 61. The planarization layer 3 has a via hole, and the first electrode 61 is connected to the source electrode 22 or the drain electrode 23 of the drive circuit through the via hole.

In some embodiments, as illustrated in FIG. 3, adjacent two isolation structures 5 form a first opening 100, the light-emitting layer 62 and the second electrode 63 are in the first opening 100, each of the isolation structures 5 is provided with a conductive portion (not illustrated), adjacent two second electrodes 63 are separated by an isolation structure 5, the second electrode 63 is lap-joined to the conductive portion of the isolation structure 5.

In this embodiment, the isolation structure 5 at least partially forms a conductive portion, allowing adjacent second electrodes 63 to establish electrical connections through the conductive portion, thereby forming a mesh-interconnected second electrode mesh, the second electrode mesh may further be connected to a circuit interface, which may achieve that only one circuit interface is needed to achieve electrical connection in the second electrode mesh. The conductive portion of the isolation structure 5 is lap-joined to the second electrode 63, which may avoid poor contact.

In some embodiments, the material of the isolation structure 5 is a combination of multiple metals or metal nitrides. For example, the material of isolation structure 5 includes Ti/Al/Ti or SiN/Ti/Al/Ti.

In some embodiments, as illustrated in FIG. 3, the display panel further includes a pixel definition layer 4. The pixel definition layer 4 is arranged on a side of the isolation structure 5 facing the substrate, and the pixel definition layer 4 includes a plurality of pixel definition units 41 arranged in an array; and in the direction perpendicular to the substrate 1, an orthographic projection of the isolation structure 5 onto the substrate 1 is within an orthographic projection of the pixel definition unit 41 onto the substrate 1.

In this embodiment, the approximate position of the light-emitting unit is determined through the pixel definition layer 4, such that the position of the isolation structure 5 may be determined. Therefore, after forming the pixel definition layer 4 on the display panel, the isolation structure 5 may be directly formed based on the position of the pixel definition layer 4. Since the orthographic projection of the isolation structure 5 onto the substrate 1 is within the orthographic projection of the pixel definition unit 41 onto the substrate 1, when evaporating the light-emitting material on the front side, the light-emitting layer 62 includes a central region and edge regions on two sides, where the central region is in the pixel definition region formed by adjacent two pixel definition units 41, and the two edge regions may cover the edges of the pixel definition unit 41, thus enabling the actual light-emitting area of the light-emitting layer 62 to be larger than the area of the pixel definition region. Therefore, the gap between adjacent light-emitting elements may be decreased, the light-emitting area of the light-emitting elements in the display panel is increased, and the aperture ratio is increased, thereby the light extraction efficiency is improved, which may further enhance the brightness of the display panel.

In some embodiments, the pixel definition layer 4 includes an organic insulating material, which may include polyimide (PI), benzocyclobutene (BCB), and a photoresist material.

In some embodiments, as illustrated in FIG. 3, a second opening 200 is formed between adjacent two of the pixel definition units 41, the second opening 200 is within the first opening 100, and an opening direction of the second opening 200 is the same as an opening direction of the first opening 100. The first electrode 61 is arranged on a side of the second opening 200 facing the substrate 1, a plurality of the first electrodes 61 are connected to a light-emitting layer 62 respectively, and adjacent two of the first electrodes 61 are separated by a pixel definition layer 4. In this embodiment, the second opening 200 of the pixel definition unit 41 may be configured to limit the position of the light-emitting layer 62, and the first groove 501 of the second opening 200 may accommodate the light-emitting material to increase the thickness of the light-emitting material and improve the brightness. The pixel definition layer may separate the first electrodes 61 to avoid a parallel short circuit between the circuits.

It should be noted that, in some embodiments, when the isolation structure 5 includes a non-conductive material, the pixel definition layer 4 may be omitted, and the first electrodes 61 may be separated by the isolation structure 5, which may further reduce the thickness of the film structure of the display panel and enhance the user experience.

In some embodiments, as illustrated in FIG. 3, in the direction perpendicular to the substrate 1, an orthographic projection of the isolation structure 5 onto the substrate 1 and an orthographic projection of the light-emitting layer 62 onto the substrate 1 are not overlapped.

In this embodiment, the projection areas of the orthographic projections of the isolation structure 5 and the light-emitting layer 62 onto the display panel are not overlapped. On the one hand, the shielding of the light-emitting layer 62 caused by the isolation structure 5 may be avoided, such that the light emitted by the light-emitting layer 62 may be maximally utilized. On the other hand, during the formation of the light-emitting layer 62, the situation that a redundant light-emitting layer 62 for other colors is deposited in the edge regions and is not etched may be avoided, such that cross-color contamination between individual light-emitting elements may be avoided.

In some embodiments, as illustrated in FIG. 3, the first auxiliary layer 8 includes a light-transmitting material, and the first auxiliary layer 8 is at least partially arranged on a side of the display function layer 6 away from the substrate 1. In the direction perpendicular to the substrate 1, an orthographic projection of the first auxiliary layer 8 onto the substrate 1 at least partially covers an orthographic projection of an edge region of the display function layer 6 close to the isolation structure 6 onto the substrate 1. In this embodiment, the first auxiliary layer 8 includes a light-transmitting material and arranged on the light-emitting layer 62 away from the substrate 1, may adjust the light emitted by the light-emitting layer 62 through the first auxiliary layer 8, thereby improving the utilization rate of light.

In some embodiments, as illustrated in FIG. 3, the display panel further includes a second auxiliary layer 9, where the second auxiliary layer 9 includes a light-transmitting material. The second auxiliary layer 9 is arranged on a side of the first auxiliary layer 8 away from the substrate 1, the refractive index of the second auxiliary layer 9 is not equal to the refractive index of the first auxiliary layer 8. In this embodiment, a second auxiliary layer 9 is provided on the first auxiliary layer 8, and the refractive indices of the first auxiliary layer 8 and the second auxiliary layer 9 are not equal, thus forming an interface for adjusting the light exit angle, which may increase the exit angle of light and improve the light extraction efficiency and light utilization rate. In addition, in the manufacturing technique, if the first auxiliary layer 8 does not completely fill up the second groove 701 of the first encapsulation layer 7, the second auxiliary layer 9 may also assist in filling up the second groove 701, so as to avoid stress concentration.

In some embodiments, the refractive index of the second auxiliary layer 9 is greater than the refractive index of the first auxiliary layer 8.

In some embodiments, the difference between the refractive index of the second auxiliary layer 9 and the refractive index of the first auxiliary layer 8 is greater than 0.16.

In some embodiments, the refractive index of the first refraction layer 8 is a value from 1.4 to 1.6, and the refractive index of the second refraction layer 9 isa from 1.7 to 1.9.

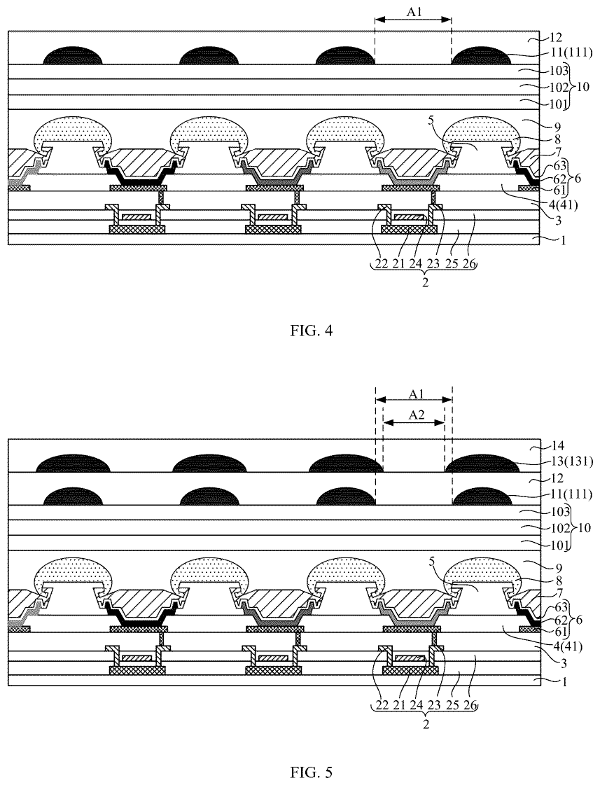

In some embodiments, as illustrated in FIG. 4 to FIG. 8, the display panel further includes a second encapsulation layer 10 on the second auxiliary layer 9, the second encapsulation layer 10 includes a first inorganic layer 101, a first organic layer 102, and a second inorganic layer 103 that are sequentially stacked. The second encapsulation layer 10 may encapsulate the entire display panel, to prevent the function film layer in the display panel from being eroded by water vapor, which improves device stability.

In some embodiments, as illustrated in FIG. 4, the display panel further includes a first light shielding layer 11 and a first planarization layer 12 sequentially arranged on a side of the second auxiliary layer 9 away from the first auxiliary layer 8, the first light shielding layer 11 includes a plurality of first light shielding units 111 arranged spaced apart, the first planarization layer 12 is at least partially arranged in a first spacing region A1 between adjacent two of the first light shielding units 111, and in the direction perpendicular to the substrate 1, an orthographic projection of the first spacing region A1 onto the substrate 1 at least partially covers an orthographic projection of the light-emitting layer 62 onto the substrate 1.

In this embodiment, the combination between the first light shielding layer 11 and the isolation structure 5 increases the light blocking structure on a side of the light-emitting layer 62, thereby achieving a side anti-peeping design. In some embodiments, the first light shielding layer 11 may surround the light-emitting element, further achieving omnidirectional anti-peeping.

In some embodiments, as illustrated in FIG. 5, the display panel further includes a second light shielding layer 13 and a second planarization layer 14 sequentially stacked on the first planarization layer 12, the second light shielding layer 13 includes a plurality of second light shielding units 131 arranged spaced apart, the second planarization layer is at least partially arranged in a second spacing region A2 between adjacent two of second light shielding units 131, in the direction perpendicular to the substrate 1, an orthographic projection of the second spacing region A2 onto the substrate 1 at least partially covers an orthographic projection of the light-emitting layer 62 onto the substrate 1, and an orthographic projection of the second light shielding unit 131 onto the substrate 1 covers and is larger than an orthographic projection of the first light shielding unit 111 onto the substrate 1.

In this embodiment, a second light shielding layer 13 is further formed on the first light shielding layer 11, and the orthographic projection of the second light shielding layer 13 onto the substrate 1 is larger than the orthographic projection of the first light shielding layer 11 onto the substrate 1. Therefore, the anti-peeping effect may be further enhanced.

In some embodiments, the radial dimension of the orthographic projection of the second light shielding layer 13 onto the substrate 1 is a value from 10 μm to 30 μm larger than the radial dimension of the orthographic projection of the first light shielding layer 11 onto the substrate 1.

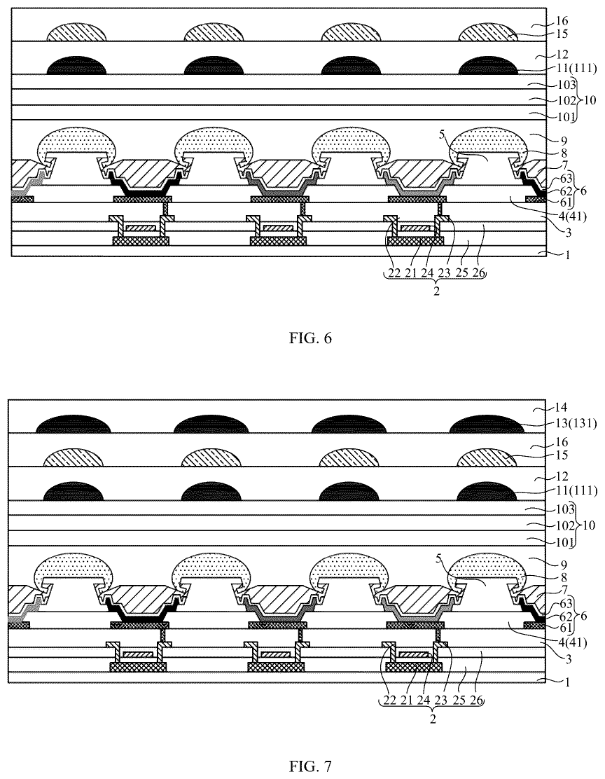

In some embodiments, as illustrated in FIG. 6, the display panel further includes a first light adjusting layer 15 and a second light adjusting layer 16 sequentially stacked on the first planarization layer 12, and in the direction perpendicular to the substrate 1, the overlapping region between the orthographic projection of the first light adjusting layer 15 onto the substrate 1 and the orthographic projection of the second light adjusting layer 16 onto the substrate 1 at least partially covers the orthographic projection of the light-emitting layer 62 onto the substrate 1.

In this embodiment, by arranging the first light adjusting layer 15 and the second light adjusting layer 16 on the first light shielding layer 11, the light emitted through the anti-peeping structure may be further concentrated and then exit, and then to improve the brightness of the display panel.

It should be noted that, several first light adjusting layers and second light adjusting layers are further stacked on both sides of each light shielding layer as well as the corresponding planarization layer 3, which those skilled in the art may flexibly design, but are not limited thereto. As illustrated in FIG. 7, the second light shielding layer 13 and the second planarization layer 14 may be stacked on the first light adjusting layer 15 and the second light adjusting layer 16 that are stacked on the first planarization layer 12, so as to further enhance the anti-peeping effect.

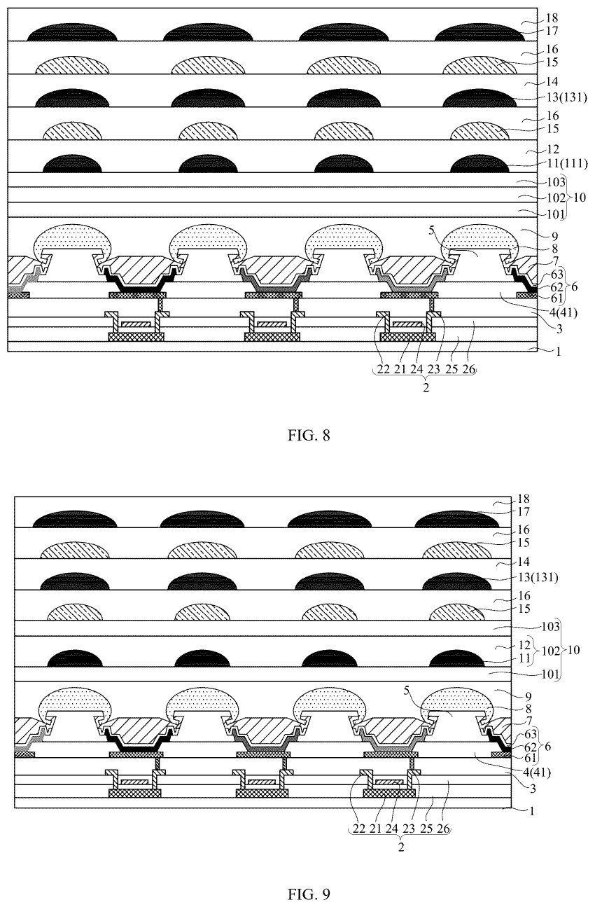

In some embodiments, as illustrated in FIG. 8, the display panel further includes a third light shielding layer 17 and a third planarization layer 18 stacked on the second planarization layer 14. It has been verified by experiments that the anti-peeping effect is better by arranging three light shielding layers.

In additional, as illustrated in FIG. 9, the first light shielding layer 11 and the first planarization layer 12 may serve as the first organic layer 102 in the second encapsulation layer 10, to further reduce the thickness of the display panel.

In some embodiments, as illustrated in FIG. 10, the display panel further includes a light filter layer 19 stacked on the second auxiliary layer 9. The light filter layer 19 includes light shielding units and light filter units that are alternately arranged. In the direction perpendicular to the substrate 1, the orthographic projection of the light filter unit onto the substrate 1 at least partially covers the orthographic projection of the light-emitting layer 62 onto the substrate 1. The light filter layer 19 in this embodiment may further enhance the light extraction efficiency of the display panel, so as to optimize the display effect.

In some embodiments, the display panel further includes a first light adjusting layer 15 and a second light adjusting layer 16 (not illustrated) stacked on the light filter layer 19 to adjust the light exit angle and light extraction efficiency of the display panel.

In some embodiments, in a direction from the substrate 1 towards the display function layer 6, the projection area of the orthographic projection of the isolation structure 5 onto the substrate 1 gradually increases.

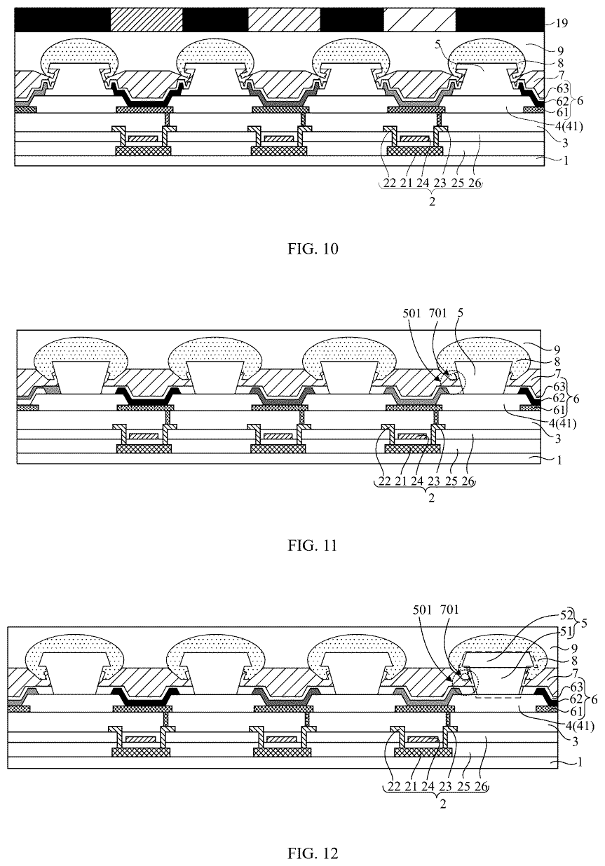

In some embodiments, the side of isolation structure 5 is a straight, curved, stepped, or serrated surface. In this embodiment, the connection surfaces of the isolation structure 5 and the display function layer 6 form a first groove 501. For example, as illustrated in FIG. 11, the shape of the isolation structure 5 is an inverted trapezoid.

In some embodiments, the isolation structure 5 includes a first isolation portion 51 and a second isolation portion 52 sequentially stacked on the substrate 1, and in the direction perpendicular to the substrate 1, an orthographic projection of an end face of the first isolation portion 51 facing the second isolation portion 52 onto the substrate 1 is within an orthographic projection of the second isolation portion 52 onto the substrate 1. In this embodiment, connection surfaces of the first isolation portion 51 and the second isolation portion 52 form a first groove 501. For example, as illustrated in FIG. 12, the first isolation portion 51 is an isolation column, and the second isolation portion 52 is an eave structure.

In some embodiments, as illustrated in FIG. 3, the isolation structure 5 includes a third isolation portion 53, a first isolation portion 51, and a second isolation portion 52 sequentially stacked on the substrate 1, and in the direction perpendicular to the substrate 1, an orthographic projection of the second isolation portion 52 onto the substrate 1 is within an orthographic projection of the third isolation portion 53 onto the substrate 1, and an orthographic projection of the first isolation portion 51 onto the substrate 1 is within an orthographic projection of the second isolation portion 52 onto the substrate 1. In this embodiment, the connection surfaces of the first isolation portion 51, the second isolation portion 52, and the third isolation portion 53 form a first groove 501. For example, as illustrated in FIG. 3, the shape of the isolation structure 5 in this embodiment is I-shaped, and the third isolation portion 53 is provided at the bottom of the isolation structure 5, which may further restrict the diffusion region of the light-emitting layer 62, suppress the projection region for the orthographic projection of the light-emitting layer 62 onto the substrate 1 from exceeding the projection region for the orthographic projection of the second isolation portion 52 of the isolation structure 5 onto the substrate 1, and to be more conducive to controlling the coverage region of the light-emitting layer 62 in the evaporation technique, and improve the utilization rate of the light-emitting layer 62.

In some embodiments, as illustrated in FIG. 3, the radial dimension of the orthographic projection of the isolation structure 5 onto the substrate 1 is a value from 3 μm to 5 μm.

In some embodiments, as illustrated in FIG. 13, the first encapsulation layer 7 is further in the border region, and in a direction from the display function layer 6 towards the substrate 1, a projection area of an orthographic projection of the first encapsulation layer 7 onto the substrate 1 gradually increases.

In this embodiment, the first encapsulation layer 7 in the border region has a slope-like shape, which may avoid the film layer boundaries in the display panel from being flush at the boundary in the vertical direction, achieve reduction of stress accumulation, and improve structural stability. At the same time, this may avoid poor continuity or even breakage of the film layer deposited on the first encapsulation layer 7 due to step differences.

In some embodiments, as illustrated in FIG. 13, the first encapsulation layer 7 in the border region includes a first encapsulation sub-layer 71, a second encapsulation sub-layer 72, and a third encapsulation sub-layer 73 sequentially stacked on the substrate 1. The radial dimension of the projection area for the orthographic projection of the first encapsulation sub-layer 71 onto the substrate 1 is 5 μm to 20 μm larger than the radial dimension of the projection area for the orthographic projection of the second encapsulation sub-layer 72 onto the substrate 1, and the radial dimension of the projection area for the orthographic projection of the second encapsulation sub-layer 72 onto the substrate 1 is 5 μm to 20 μm larger than the radial dimension of the projection area for the orthographic projection of the third encapsulation sub-layer 73 onto the substrate 1. For example, the radial dimension of the projection area for the orthographic projection of the first encapsulation sub-layer 71 onto the substrate 1 is 10 μm larger than the radial dimension of the projection area for the orthographic projection of the second encapsulation sub-layer 72 onto the substrate 1, and the radial dimension of the projection area for the orthographic projection of the second encapsulation sub-layer 72 onto the substrate 1 is 10 μm larger than the radial dimension of the projection area for the orthographic projection of the third encapsulation sub-layer 73 onto the substrate 1.

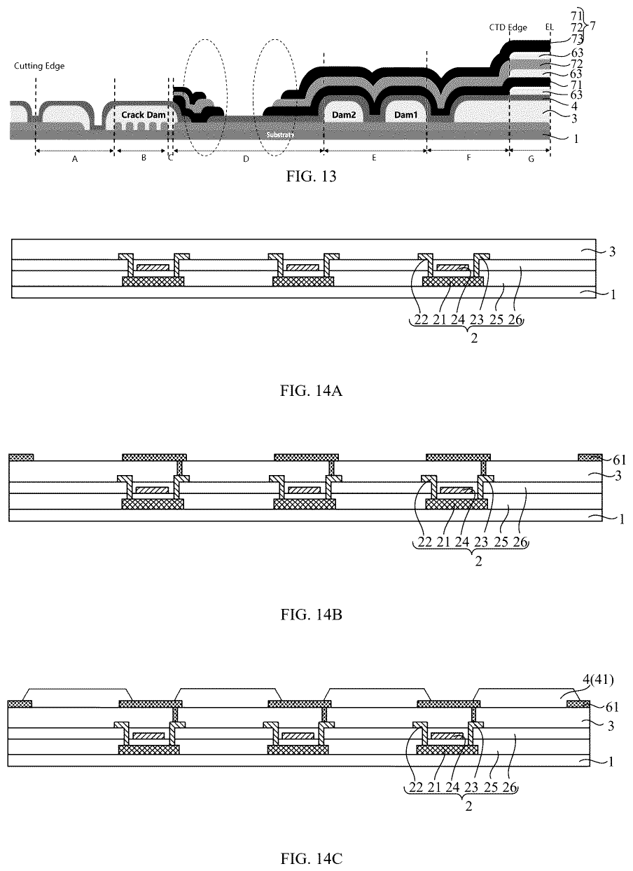

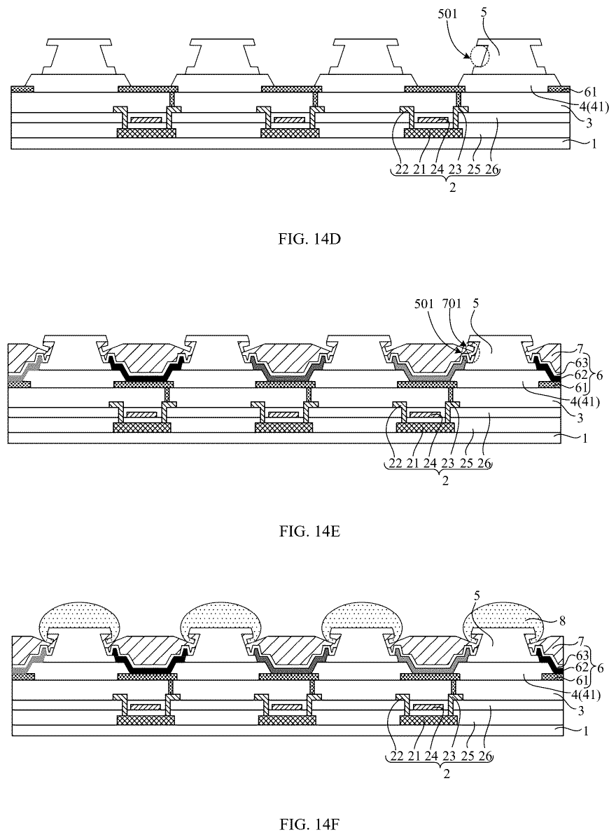

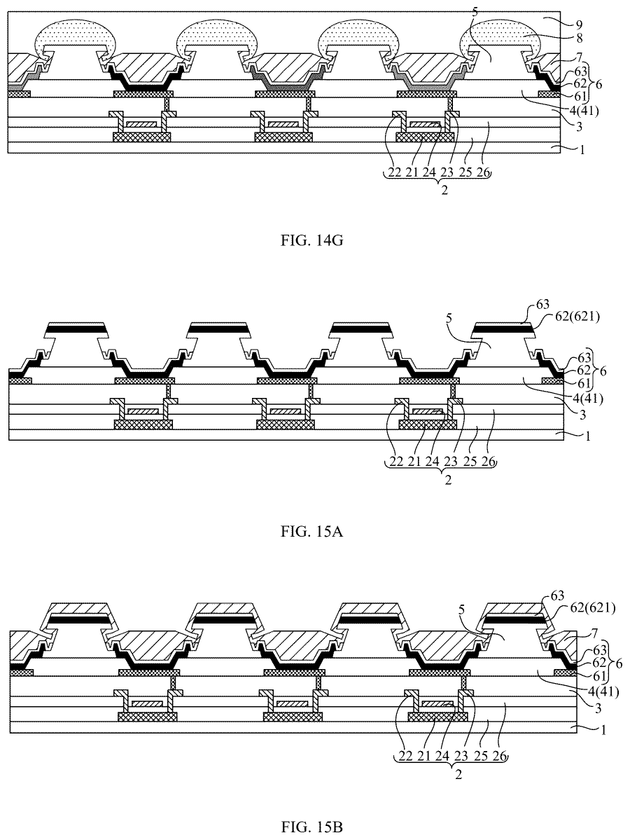

Based on the same inventive concept, the present disclosure further provides a method of manufacturing a display panel, including the following steps:
at step 100: as illustrated in FIG. 14A, forming a drive circuit layer 2 and a planarization layer 3 stacked on a substrate 1;
at step 200: as illustrated in FIG. 14B, forming a first electrode 61 on the planarization layer 3;
at step 300: as illustrated in FIG. 14C, forming a pixel definition layer 4 on the first electrode 61, where the pixel definition layer 4 includes a plurality of pixel definition units 41 arranged spaced apart;
at step 400: as illustrated in FIG. 14D, forming isolation structures 5 on the pixel definition units 41, where a surface of the isolation structure 5 extending in a direction perpendicular to the substrate 1 has a first groove 501, and forming a first opening 100 between adjacent two of the isolation structures 5;
at step 500: as illustrated in FIG. 14E, forming a light-emitting layer 62, a second electrode 63, and a first encapsulation layer 7 stacked in the first opening 100, where a second groove 701 is formed in an edge region of the first encapsulation layer 7 close to the isolation structure 5, and in a direction from the isolation structure 5 towards the substrate 1, the first encapsulation layer 7 is at least partially covered by the isolation structure 5; and
at step 600: as illustrated in FIG. 14F, forming a first auxiliary layer 8 on a side of the first encapsulation layer 7 away from the display function layer 6, where the first auxiliary layer 8 is at least partially filled in the second groove 701.

In this embodiment, with such a structure of the isolation structure 5, the first encapsulation layer 7, and the first auxiliary layer 8, since the isolation structure 5 may serve as a partition between the light-emitting layers 62, the light-emitting elements arranged in an array may be manufactured without adopting a fine metal mask. In addition, the first encapsulation layer 7 may resist the erosion of moisture on the light-emitting layer 62, and the first auxiliary layer 8 is at least partially covered by the isolation structure 5, which may avoid stress concentration at the top of the isolation structure 5 and improve the structural stability and reliability of the display panel.

In some embodiments, in the direction parallel to the substrate 1, the first openings 100 include first sub-openings, second sub-openings, and third sub-openings arranged in an array, the light-emitting layers 62 include first light-emitting layers, second light-emitting layers, and third light-emitting layers arranged in an array, the first sub-opening, the second sub-opening, and the third sub-opening correspond to the first light-emitting layer, the second light-emitting layer, and the third light-emitting layer, respectively, light colors emitted by the first light-emitting layer 621, the second light-emitting layer, and the third light-emitting layer are different. Step 500 specifically includes: by using a photolithography technique, sequentially forming the first light-emitting layer in the first sub-opening, the second light-emitting layer in the second sub-opening, and the third light-emitting layer in the third sub-opening, as well as the second electrode 63 and the first encapsulation layer 7 in the first opening 100.

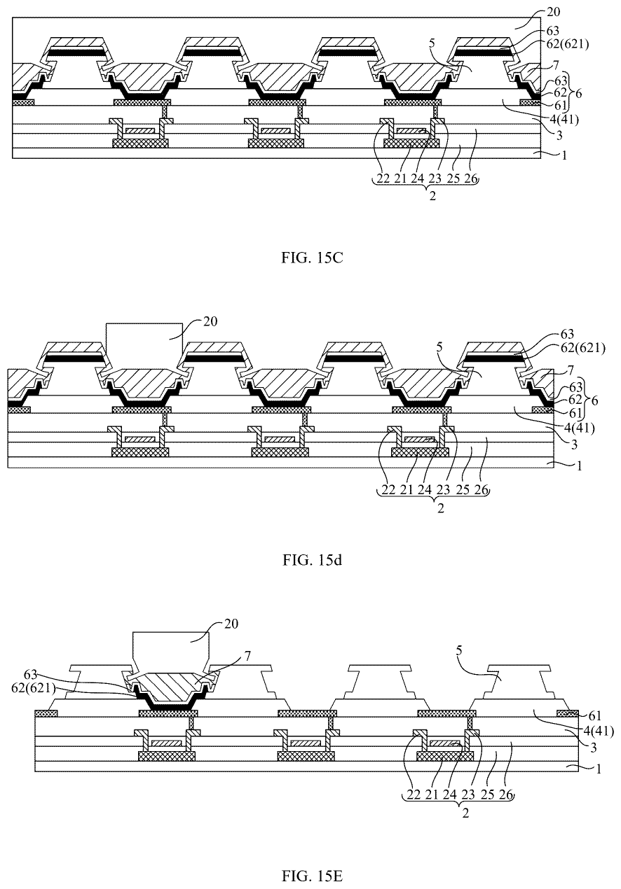

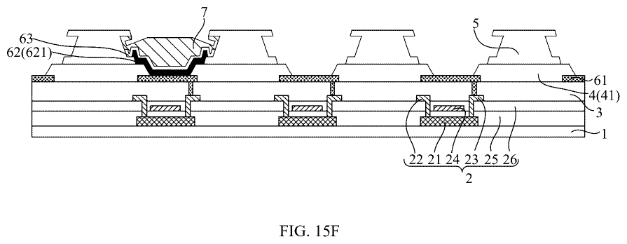

For example, for manufacturing a first light-emitting layer 621, step 500 includes the following steps:
at step 510: as illustrated in FIG. 15A, an entire first light-emitting layer 621 and an entire second electrode 63 are sequentially stacked on a side of the isolation structure 5 away from the substrate 1;
at step 520: as illustrated in FIG. 15B, a side of the second electrode 63 away from the substrate 1 is covered with a first encapsulation layer 7;
at step 530: as illustrated in FIG. 15C, the encapsulation layer 7 is covered with a photoresist 20;
at step 540: as illustrated in FIG. 15d, the photoresist 20 is exposed and developed by using yellow light technique, the photoresist 20 at the first sub-opening is retained, and the two sides of the photoresist 20 are flush with the two ends of the isolation structure 5;
at step 550: as illustrated in FIG. 15E, the second electrode 63 and the first light-emitting layer 621 outside the region covered by the photoresist 20 are etched until the isolation structure 5 or the first electrode 61 is exposed;
at step 560: as illustrated in FIG. 15F, the photoresist 20 is removed.

The manufacturing process of the second light-emitting layer and the third light-emitting layer is the same as that of the first light-emitting layer 621, which is therefore not be repeated here.

In this embodiment, photolithography is used, so it is not necessary to use an FMM to form monochromatic light-emitting elements. The manufacturing technique is not limited by the FMM, which may further narrow the spacing between the light-emitting layers 62, and improve the light-emitting effect and light extraction efficiency.

In some embodiments, the first light-emitting sub-layer 62 emits green light, the second light-emitting sub-layer 62 emits blue light, and the third light-emitting sub-layer 62 emits red light. It should be noted that, in some embodiments, the light-emitting layer 62 further includes a fourth light-emitting sub-layer 62, the fourth light-emitting layer 62 emits white light, and the manufacturing principle of which is the same as that of the first light-emitting sub-layer 62 and the second light-emitting sub-layer 62.

In some embodiments, after step 600 in the method of manufacturing a display panel, the following steps are further included:
at step 700: as illustrated in FIG. 14G, forming a second auxiliary layer 9 on the first auxiliary layer 8, the refractive index of the second auxiliary layer 9 is not equal to the refractive index of the first auxiliary layer 8.

In this embodiment, by adding a second auxiliary layer 9 and cooperating with the first auxiliary layer 8, the light exit angle may be adjusted, thereby increasing the light extraction efficiency of the display panel.

Based on the same inventive concept, the present disclosure further provides another method of manufacturing a display panel, where the light-emitting layers 62 of the display panel include first light-emitting layers 621, second light-emitting layers, and third light-emitting layers, arranged in an array, and light colors emitted by the first light-emitting layer 621, the second light-emitting layer, and the third light-emitting layer are different. Specifically, the method includes the following steps:
at step 100: forming a drive circuit layer 2 and a planarization layer 3 stacked on a substrate 1;
at step 200: forming a first electrode 61 on the planarization layer 3;
step 300′: forming a pixel definition layer 4 corresponding to the first light-emitting layer 621 on the first electrode 61, where the pixel definition layer 4 includes a plurality of pixel definition units 41 arranged spaced apart;
at step 400′: forming isolation structures 5 on the pixel definition units, where a surface of the isolation structure 5 extending in a direction perpendicular to the substrate 1 has a first groove 501, and forming a first opening 100 between adjacent two of the isolation structures 5;
at step 500′: forming a light-emitting layer 621, a second electrode 63, and a first encapsulation layer 7 stacked in the first opening 100, where a second groove 701 is formed in an edge region of the first encapsulation layer 7 close to the isolation structure 5, and in a direction from the isolation structure 5 towards the substrate 1, the first encapsulation layer 7 is at least partially covered by the isolation structure 5;
at step 600′: repeating step 300′ ~step 500′ for the second light-emitting layer and the third light-emitting layer, and forming a second light-emitting layer, a second electrode 63, and a first encapsulation layer 7 stacked in the second opening 200, and forming a third light-emitting layer, a second electrode 63, and a first encapsulation layer 7 stacked in the third opening.
at step 700′: forming a first auxiliary layer 8 on a side of a first encapsulation layer 7 away from the display function layer 6, where the first encapsulation layer 7 is in the first opening 100, the second opening 200, and the third opening, and first auxiliary layer 8 is at least partially filled in the second groove 701.

In this embodiment, by sequentially forming the pixel definition layer 4 and the isolation structure 5 corresponding to a monochromatic light-emitting layer 62, when forming the monochromatic light-emitting layer 62, the structure of the other monochromatic light-emitting layers 62 may not be affected. Moreover, if photolithography is used to etch the stacked light-emitting layer 62 and the second electrode 63, since there are no uneven surfaces of the pixel definition layer 4 and the isolation structure 5, the etching effect is better on a flat surface.

The present disclosure provides a display device, including the display panel as described in the above embodiments. The display device has the advantages of the display panel in the above embodiments, which is therefore not repeated here.

It should be noted that, the display device may be any device that displays content, whether in motion (e.g., video) or stationary (e.g., still images), and whether textual or graphical. More specifically, the expected embodiments may be implemented in or associated with a variety of electronic devices, such as (but not limited to) mobile phones, wireless devices, personal digital assistants (PDAs), handheld or portable computers, GPS receivers/navigators, cameras, MP4 video players, camcorders, game consoles, watches, clocks, calculators, television monitors, flat panel displays, computer monitors, automotive displays (e.g., speedometer displays, etc.), navigators, cockpit controllers and/or displays, camera view displays (e.g., displays for rearview cameras in vehicles), electronic photos, electronic billboards or signs, projectors, building structures, packaging, and aesthetic structures (e.g., displays for images of a piece of jewelry), etc.

The above embodiments of the present disclosure, in the absence of conflicts, may complement each other.

It is to be noted that in the accompanying drawings, the dimensions of layers and regions may be exaggerated for clarity of illustration. It will be understood that when an element or a layer is referred to as being “above” or “on” another element or layer, it may be directly on the other element, or intervening layers may be present. In addition, it will be understood that when an element or a layer is referred to as being “under” or “below” another element or layer, it may be directly under the other element, or one or more intervening layers or elements may be present. In addition, it will also be understood that when a layer or an element is referred to as being “between” two layers or two elements, it may be the only layer between the two layers or two elements, or one or more intervening layers or elements may be present. Like reference numerals indicate like elements throughout.

The terms “center,” “up,” “bottom,” “front,” “back,” “left,” “right,” “vertical,” “horizontal,” “top,” “bottom,” “inside,” “outside,” etc., indicate orientations or positional relationships based on the orientations or positional relationships shown in the drawings and are intended solely for convenience and simplification of the present application, and do not indicate or imply that the device or element referred to must have a particular orientation, be constructed and operated in a particular orientation, and therefore cannot be construed as limiting the present application.

In addition, the terms “first” and “second” are only used for description, and cannot be construed as indicating or implying relative importance or implicitly indicating the number of indicated technical features. Thus, elements limited by “first” and “second” may explicitly or implicitly include one or more features. In the descriptions of the present disclosure, “a plurality” refers to two or more unless otherwise stated clearly.

Those skilled in the art will readily conceive other embodiments of the present disclosure upon consideration of the specification and practice of the various embodiments disclosed herein. This application is intended to cover any variation, use, or adaptive change of this application. These variations, uses, or adaptive changes follow the general principles of this application and include common general knowledge or common technical means in the art that are not disclosed in this application. The specification and the embodiments are considered as merely exemplary, and the real scope and spirit of the present disclosure are pointed out in the following claims.

It should be understood that this application is not limited to the precise structures described above and shown in the accompanying drawings, and various modifications and changes can be made without departing from the scope of this application. The scope of the present disclosure is limited only by the appended claims.

1. A display panel with a display region and a border region surrounding the display region, wherein the display panel comprises:
a substrate;
a display function layer in the display region and comprising a plurality of light-emitting elements arranged in an array, wherein each of the plurality of light-emitting elements comprises a first electrode, a light-emitting layer, and a second electrode sequentially stacked on the substrate;
isolation structures, alternately arranged in an array on the substrate with the plurality of light-emitting elements, wherein a surface of the isolation structure extending in a direction perpendicular to the substrate has a first groove;
a first encapsulation layer, covering the display function layer, wherein a second groove is formed in an edge region of the first encapsulation layer close to the isolation structure, and in a direction from the isolation structure towards the substrate, the first encapsulation layer is at least partially covered by the isolation structure; and
a first auxiliary layer, on a side of the first encapsulation layer away from the display function layer and at least partially filled in the second groove.

2. The display panel according to claim 1, wherein adjacent two of the isolation structures form a first opening, the light-emitting layer and the second electrode are in the first opening, the isolation structure is provided with a conductive portion, adjacent two second electrodes are separated by the isolation structure, the second electrode is lap-joined to the conductive portion of the isolation structure.

3. The display panel according to claim 2, wherein the display panel further comprises a pixel definition layer;
the pixel definition layer is arranged on a side of the isolation structure facing the substrate, and the pixel definition layer comprises a plurality of pixel definition units arranged in an array; and
in the direction perpendicular to the substrate, an orthographic projection of the isolation structure onto the substrate is within an orthographic projection of the pixel definition unit onto the substrate.

4. The display panel according to claim 3, wherein a second opening is formed between adjacent two of the pixel definition units, the second opening is within the first opening, and an opening direction of the second opening is same as an opening direction of the first opening; and the first electrode is arranged on a side of the second opening facing the substrate, a plurality of the first electrodes are connected to the light-emitting layer respectively, and adjacent two of the first electrodes are separated by the pixel definition layer.

5. The display panel according to claim 3, wherein in the direction perpendicular to the substrate, an orthographic projection of the isolation structure onto the substrate and an orthographic projection of the light-emitting layer onto the substrate are not overlapped.

6. The display panel according to claim 1, wherein the first auxiliary layer comprises a light-transmitting material, and the first auxiliary layer is at least partially arranged on a side of the display function layer away from the substrate; and
in the direction perpendicular to the substrate, an orthographic projection of the first auxiliary layer onto the substrate at least partially covers an orthographic projection of an edge region of the display function layer close to the isolation structure onto the substrate.

7. The display panel according to claim 6, wherein the display panel further comprises a second auxiliary layer, the second auxiliary layer comprises a light-transmitting material; and
the second auxiliary layer is arranged on a side of the first auxiliary layer away from the substrate, and a refractive index of the second auxiliary layer is not equal to a refractive index of the first auxiliary layer.

8. The display panel according to claim 7, wherein the display panel further comprises a first light shielding layer and a first planarization layer sequentially arranged on a side of the second auxiliary layer away from the first auxiliary layer, the first light shielding layer comprises a plurality of first light shielding units arranged spaced apart, the first planarization layer is at least partially arranged in a first spacing region between adjacent two of the first light shielding units, and in the direction perpendicular to the substrate, an orthographic projection of the first spacing region onto the substrate at least partially covers an orthographic projection of the light-emitting layer onto the substrate.

9. The display panel according to claim 8, wherein the display panel further comprises a second light shielding layer and a second planarization layer sequentially stacked on the first planarization layer, the second light shielding layer comprises a plurality of second light shielding units arranged spaced apart, the second planarization layer is at least partially arranged in a second spacing region between adjacent two of the second light shielding units, in the direction perpendicular to the substrate, an orthographic projection of the second spacing region onto the substrate at least partially covers an orthographic projection of the light-emitting layer onto the substrate, and an orthographic projection of the second light shielding unit onto the substrate covers and is larger than an orthographic projection of the first light shielding unit onto the substrate.

10. The display panel according to claim 8, wherein the display panel further comprises a first light adjusting layer and a second light adjusting layer sequentially stacked on the first planarization layer, in the direction perpendicular to the substrate, an overlapping region between an orthographic projection of the first light adjusting layer onto the substrate and an orthographic projection of the second light adjusting layer onto the substrate at least partially covers an orthographic projection of the light-emitting layer onto the substrate.

11. The display panel according to claim 7, wherein the display panel further comprises a light filter layer stacked on the second auxiliary layer, the light filter layer comprises light shielding units and light filter units that are alternately arranged, and in the direction perpendicular to the substrate, an orthographic projection of the light filter unit onto the substrate at least partially covers an orthographic projection of the light-emitting layer on the substrate.

12. The display panel according to claim 1, wherein in a direction from the substrate towards the display function layer, a projection area of an orthographic projection of the isolation structure onto the substrate gradually increases.

13. The display panel according to claim 1, wherein the first encapsulation layer is further in the border region, and in a direction from the display function layer towards the substrate, a projection area of an orthographic projection of the first encapsulation layer onto the substrate gradually increases.

14. A method of manufacturing a display panel, comprising:
forming a drive circuit layer and a planarization layer stacked on a substrate;
forming a first electrode on the planarization layer;
forming a pixel definition layer on the first electrode, wherein the pixel definition layer comprises a plurality of pixel definition units arranged spaced apart;
forming isolation structures on the pixel definition units, wherein a surface of the isolation structure extending in a direction perpendicular to the substrate has a first groove, and forming a first opening between adjacent two of the isolation structures;
forming a light-emitting layer, a second electrode, and a first encapsulation layer stacked in the first opening, wherein a second groove is formed in an edge region of the first encapsulation layer close to the isolation structure, and in a direction from the isolation structure towards the substrate, the first encapsulation layer is at least partially covered by the isolation structure; and
forming a first auxiliary layer on a side of the first encapsulation layer away from the display function layer, wherein the first auxiliary layer is at least partially filled in the second groove.

15. The method according to claim 14, wherein in a direction parallel to the substrate, the first opening comprises a first sub-opening, a second sub-opening, and a third sub-opening arranged in an array, the light-emitting layer comprises a first light-emitting layer, a second light-emitting layer, and a third light-emitting layer arranged in an array, the first sub-opening, the second sub-opening, and the third sub-opening correspond to the first light-emitting layer, the second light-emitting layer, and the third light-emitting layer, respectively, light colors emitted by the first light-emitting layer, the second light-emitting layer, and the third light-emitting layer are different; wherein forming the light-emitting layer, the second electrode, and the first encapsulation layer stacked in the first opening comprises:
sequentially forming, by using a photolithography technique, the first light-emitting layer in the first sub-opening, the second light-emitting layer in the second sub-opening, and the third light-emitting layer in the third sub-opening, as well as the second electrode and the first encapsulation layer in the first opening.

16. The method according to claim 14, wherein after forming the first auxiliary layer on a side of the first encapsulation layer away from the display function layer, further comprising:
forming a second auxiliary layer on the first auxiliary layer, wherein a refractive index of the second auxiliary layer is not equal to a refractive index of the first auxiliary layer.

17. A display device, comprising a display panel with a display region and a border region surrounding the display region, wherein the display panel comprises:
a substrate;
a display function layer in the display region and comprising a plurality of light-emitting elements arranged in an array, wherein each of the plurality of light-emitting elements comprises a first electrode, a light-emitting layer, and a second electrode sequentially stacked on the substrate;
isolation structures, alternately arranged in an array on the substrate with the plurality of light-emitting elements, wherein a surface of the isolation structure extending in a direction perpendicular to the substrate has a first groove;
a first encapsulation layer, covering the display function layer, wherein a second groove is formed in an edge region of the first encapsulation layer close to the isolation structure, and in a direction from the isolation structure towards the substrate, the first encapsulation layer is at least partially covered by the isolation structure; and
a first auxiliary layer, on a side of the first encapsulation layer away from the display function layer and at least partially filled in the second groove.

18. The display panel according to claim 1, wherein the isolation structure comprises a first isolation portion and a second isolation portion sequentially stacked on the substrate, and in the direction perpendicular to the substrate, an orthographic projection of an end face of the first isolation portion facing the second isolation portion onto the substrate is within an orthographic projection of the second isolation portion onto the substrate.

19. The display panel according to claim 1, wherein the isolation structure comprises a third isolation portion, a first isolation portion, and a second isolation portion sequentially stacked on the substrate, and in the direction perpendicular to the substrate, an orthographic projection of the second isolation portion onto the substrate is within an orthographic projection of the third isolation portion onto the substrate, and an orthographic projection of the first isolation portion onto the substrate is within an orthographic projection of the second isolation portion onto the substrate
